(19) United States
(12) Patent Application Publication
(10) Pub. No.: US 2012/0040504 A1
(43) Pub. Date: Feb. 16, 2012

(54) METHOD FOR INTEGRATING DRAM AND NVM

(75) Inventors: HSIN CHANG LIN, HSINCHU COUNTY (TW); CHIA-HAO TAI, HSINCHU COUNTY (TW); YANG-SEN YEN, HSINCHU COUNTY (TW); MING-TSANG YANG, HSINCHU COUNTY (TW); YA-TING FAN, HSINCHU COUNTY (TW)

(73) Assignee: YIELD MICROELECTRONICS CORP., HSINCHU COUNTY (TW)

(21) Appl. No.: 12/853,450

(22) Filed: Aug. 10, 2010

(51) Int. Cl. H01L 21/8246

(52) U.S. Cl. 438/243; 438/253; 438/257; 257/E21.662

(57) ABSTRACT

The present invention discloses a method for integrating DRAM and NVM, which comprises steps: sequentially forming on a portion of surface of a DRAM semiconductor substrate a first gate insulation layer and a first gate layer functioning as a floating gate; and implanting ion into regions of the semiconductor substrate, which are at two sides of the first gate insulation layer, to form two heavily-doped areas that are adjacent to the first gate insulation layer and respectively function as a drain and a source; respectively forming over the first gate layer a second gate insulation layer and a second gate layer functioning as a control gate. The present invention not only increases the transmission speed but also reduces the power consumption, the fabrication cost and the package cost.

### BACKGROUND OF THE INVENTION

1. Field of the Invention

The present invention relates to a method for fabricating a memory, particularly to a method for integrating DRAM and NVM.

2. Description of the Related Art

A system usually needs RAM (Random Access Memory), which can be read and written rapidly, and ROM (Read Only Memory), which can keep data when power is removed. RAM includes DRAM (Dynamic RAM) and SRAM (Static RAM). ROM includes Flash Memory and EEPROM (Electrically Erasable Programmable Read Only Memory). Both Flash Memory and EEPROM are nonvolatile memories (NVM), which are electrically erasable and programmable and able to keep data when power is removed. Therefore, Flash Memory and EEPROM are widely used in various electronic products.

Recently, the memory used in a system is required to have a greater capacity with a lower cost. In such a requirement, various fabrication processes are developed to integrate a high-capacity DRAM and a flash memory/or EEPROM in a chip. However, the fabrication process of integrating DRAM and NVM are very complicated and expensive. Further, too much time and money is usually spent in developing the abovementioned process. For example, in the MCP (Multiple Chip Package) technology of mobile phones, a flash chip and a DRAM chip are packaged in an encapsulation with two sets of I/O pads equipped therein. Such a technology has higher complexity and higher cost. Further, two independent IC chips consume more power. Besides, MCP booting takes too much time because data must be transferred from ROM to DRAM.

Accordingly, the present invention proposes a method for integrating DRAM and NVM to overcome the abovementioned problems.

### SUMMARY OF THE INVENTION

The primary objective of the present invention is to provide a method for integrating DRAM (Dynamic Random Access Memory) and NVM (Non-Volatile Memory), which is based on the DRAM process, whereby are reduced the fabrication cost, package cost and power consumption, and whereby is increased the transmission speed.

To achieve the abovementioned objective, the present invention proposes a method for integrating DRAM and NVM, which comprises steps: providing a DRAM semiconductor substrate; sequentially forming on a portion of the surface of the DRAM semiconductor substrate a first gate insulation layer and a first gate layer functioning as a floating gate; implanting ion into the regions of the semiconductor substrate, which are at two sides of the first gate insulation layer, to form two heavily-doped areas, which are adjacent to the first gate insulation layer and respectively function as the drain and the source; sequentially forming over the first gate layer a second gate insulation layer and a second gate layer functioning as a control gate.

Below, the embodiments are described in detail in cooperation with the drawings to make easily understood the technical contents, characteristics and accomplishments of the present invention.

### BRIEF DESCRIPTION OF THE DRAWINGS

FIGS. 1(a)-1(d) are sectional views schematically showing the steps of a method for integrating DRAM and NVM according to a first embodiment of the present invention;

FIG. 2 is a sectional view schematically showing the integration of a stack-type capacitor structure and NVM according to the first embodiment of the present invention;

FIG. 3 is a sectional view schematically showing the integration of a trench-type capacitor structure and NVM according to the first embodiment of the present invention;

FIG. 4 is a sectional view schematically showing the operation of NVM according to the first embodiment of the present invention;

FIGS. 5(a)-5(c) are sectional views schematically showing the steps of a method for integrating DRAM and NVM according to a second embodiment of the present invention;

FIG. 6 is a sectional view schematically showing the integration of a stack-type capacitor structure and NVM according to the second embodiment of the present invention;

FIG. 7 is a sectional view schematically showing the integration of a trench-type capacitor structure and NVM according to the first embodiment of the present invention; and

FIG. 8 is a sectional view schematically showing the operation of NVM according to the second embodiment of the present invention.

### DETAILED DESCRIPTION OF THE INVENTION

Generally to speak, DRAM and NVM are hard to be integrated into the same chip because the fabrication processes thereof are different. However, many applications use DRAM and NVM (EEPROM or FLASH) simultaneously. Especially in a handheld electronic product, DRAM and FLASH are enveloped in the same package, which increases the area and package cost but decreases the transmission speed.

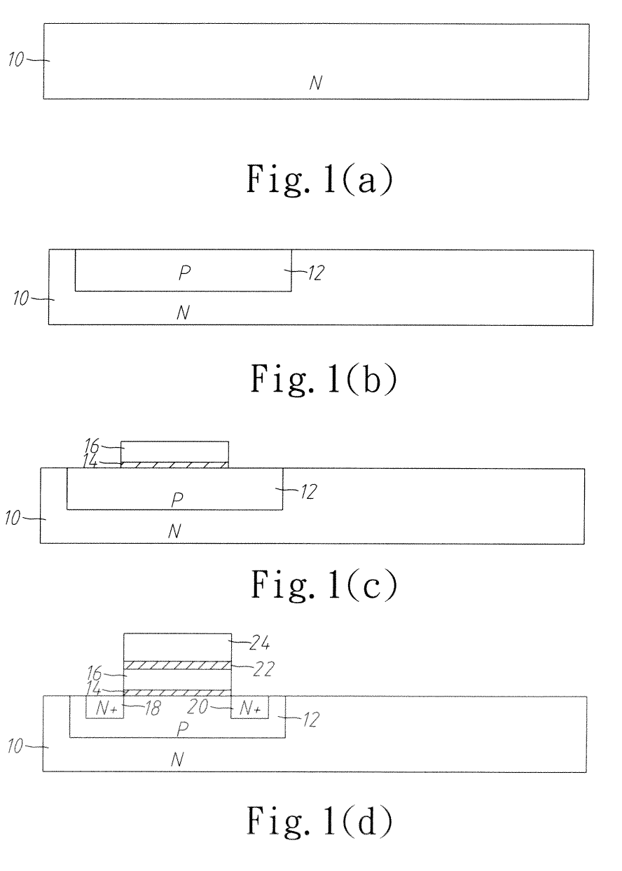

To overcome the abovementioned problems, the present invention proposes a method for integrating DRAM and NVM. Refer to FIGS. 1(a)-1(d) for a first embodiment of the present invention. Firstly, provide an n-type semiconductor substrate 10 functioning as a DRAM semiconductor substrate, as shown in FIG. 1(a). Next, form a p-type well 12 in the n-type semiconductor substrate 10, as shown in FIG. 1(b). Next, sequentially form a first gate insulation layer 14 and a first gate layer 16 on the surface of the p-type well 12, as shown in FIG. 1(c). The first gate insulation layer 14 is made of silicon dioxide. The first gate layer 16 is made of a polysilicon material. Next, implant n-type ion into the regions of the p-type well 12, which are at two sides of the first gate insulation layer 14, to form two n-type heavily-doped areas 18 and 20 that are adjacent to the first gate insulation layer 14 and respectively function as the source and the drain, as shown in FIG. 1(d). Next, sequentially form over the first gate layer 16 a second gate insulation layer 22 and a second gate layer 24 functioning as a control gate. The second gate insulation layer 22 is thicker than the first gate insulation layer 14. The second gate insulation layer 22 is an ONO (Oxide-Nitride-Oxide) layer or a TEOS (tetraethyl-ortho-silicate) layer. The second gate 24 is made of a polysilicon material.

In FIG. 1(d), the two heavily-doped n-type areas 18 and 20 may be firstly formed in the p-type well 12, and then the second gate insulation layer 22 and the second gate layer 24 are sequentially formed over the first gate layer 16. Alternatively, the second gate insulation layer 22 and the second gate layer 24 are sequentially formed over the first gate layer 16 before the two heavily-doped n-type areas 18 and 20 are formed in the p-type well 12. In the two methods, the floating gate and the control gate are exempted from line-to-line alignment. Therefore, the layers of the photomasks, the complexity of fabrication and the cost of fabrication are greatly reduced.

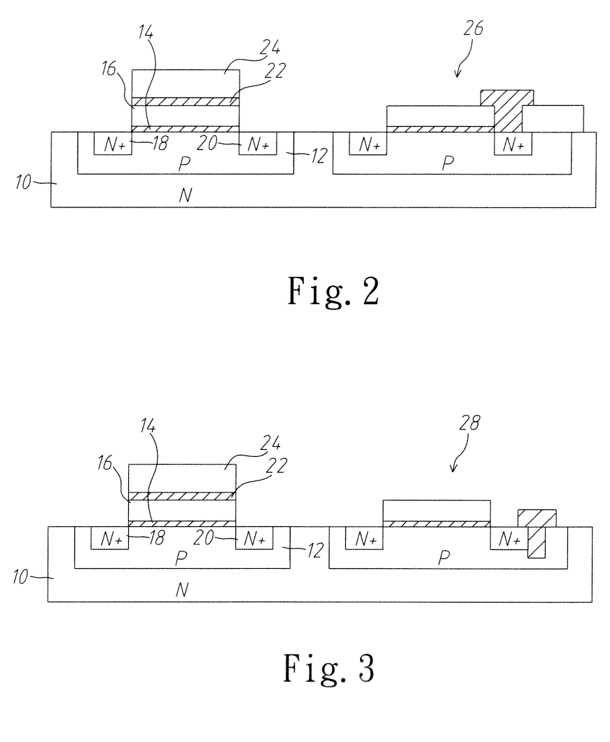

The fabrication of NVM according to the first embodiment of the present invention has been completed in FIG. 1(d). Refer to FIG. 2 for the integration of NVM and DRAM, wherein a stack-type capacitor structure 26 is formed on the n-type semiconductor substrate 10. If the DRAM has a trench-type capacitor structure, form a trench-type capacitor structure 28 in the n-type semiconductor substrate 10 after the step of FIG. 1(a). Then, sequentially undertake the steps of from FIG. 1(b) to FIG. 1(d) to form the structure shown in FIG. 3. The present invention embeds EEPROM into DRAM, whereby is reduced the package cost, and whereby is saved one set of I/O pad. Thus, data lines can be widened to increase the transmission speed and decrease the power consumption.

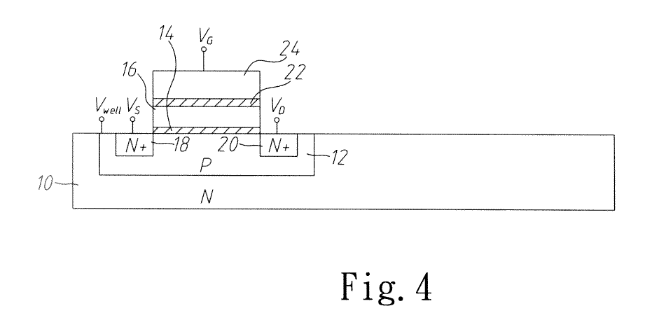

Below is described the operation of a nonvolatile memory fabricated according to the first embodiment of the present invention. Refer to FIG. 4. In operation, a drain voltage V_{D}, a source voltage V_{S}, a gate voltage V_{G} and a well voltage V_{well} are respectively applied to the above-mentioned drain, source, control gate and the p-type well 12. In a write activity, the abovementioned voltages satisfy the following conditions: V_{well} is grounded; V_{D}>V_{S}>0, and V_{G}>V_{S}>0. The present invention adopts a hot electron program method and needn't use a voltage higher than 8V. Thus, the layers of photomasks are greatly decreased. In an erase activity, the abovementioned voltages satisfy the following conditions: V_{well} is grounded; V_{D}>>V_{S}≧0, and V_{G}≧V_{S}≧0. The present invention adopts a hot hole erase method and needn't use a voltage higher than 8V. Thus, the layers of photomasks are greatly decreased. When data is transmitted from EEPROM to DRAM, signals needn't pass through the I/O pad, whereby is accelerated the transmission speed, and whereby the data lines can be widened.

In the above description of the first embodiment, an n-type transistor is used to exemplify the first embodiment of the present invention. The present invention also applies to a p-type transistor, wherein the n-type semiconductor substrate 10, the p-type well 12 and the n-type heavily-doped areas 18 and 20 are respectively replaced by a p-type semiconductor substrate, an n-type well and two p-type heavily-doped areas.

In the operation of a p-type transistor of the first embodiment, a drain voltage V_{D}, a source voltage V_{S}, a gate voltage V_{G} and a well voltage V_{well} are respectively applied to the drain, source, control gate and the n-type well. In a write activity, the abovementioned voltages satisfy the following conditions: V_{well}>V_{S}>V_{D}, and V_{well}>V_{S}>V_{G}. In an erase activity, the abovementioned voltages satisfy the following conditions:

V_{well}=V_{S}≧V_{G}>V_{D}.

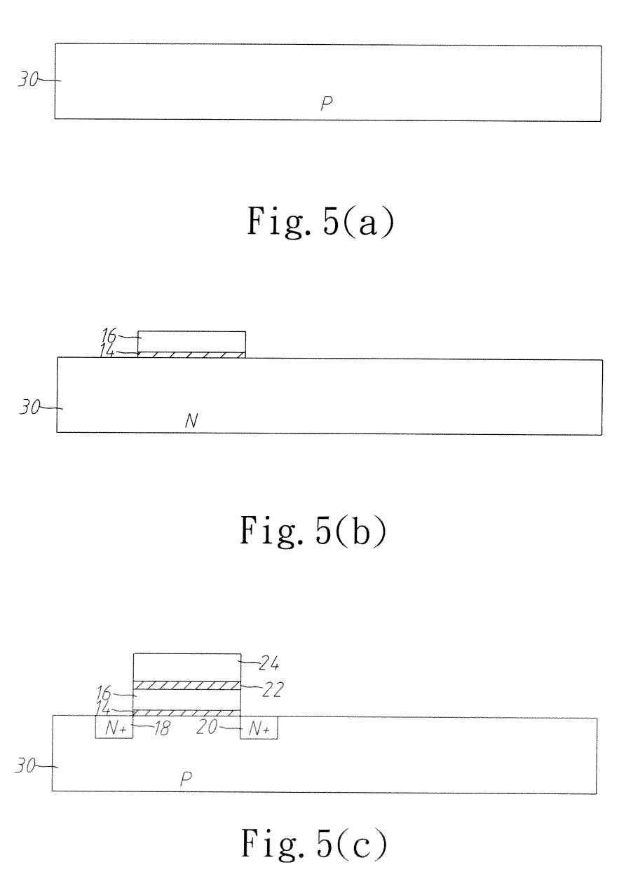

Refer to FIGS. 5(a)-5(c) for a second embodiment of the present invention. The second embodiment is different from the first embodiment in that no well is used in the second embodiment. Firstly, provide a p-type semiconductor substrate 30, as shown in FIG. 5(a). Next, form a first gate insulation layer 14 and a first gate layer 16 on the p-type semiconductor substrate 30, as shown in FIG. 5(b). The first gate insulation layer 14 is made of silicon dioxide. The gate layer 16 is made of a polysilicon material. Next, implant n-type ion into the regions of the p-type semiconductor substrate 30, which are at two sides of the first gate insulation layer 14, to form two n-type heavily-doped areas 18 and 20 that are adjacent to the first gate insulation layer 14 and respectively function as the source and the drain, as shown in FIG. 5(c). Next, sequentially form over the first gate layer 16 a second gate insulation layer 22 and a second gate layer 24 functioning as a control gate. The second gate insulation layer 22 is thicker than the first gate insulation layer 14. The second gate insulation layer 22 is an ONO (Oxide-Nitride-Oxide) layer or a TEOS (tetraethyl-ortho-silicate) layer. The second gate layer 24 is made of a polysilicon material.

In FIG. 5(c), the two heavily-doped n-type areas 18 and 20 may be firstly formed in the p-type semiconductor substrate 30, and then the second gate insulation layer 22 and the second gate layer 24 are sequentially formed over the first gate layer 16. Alternatively, the second gate insulation layer 22 and the second gate layer 24 are sequentially formed over the first gate layer 16 before the two heavily-doped n-type areas 18 and 20 are formed in the p-type semiconductor substrate 30. The objectives and efficacies of the abovementioned two steps are similar to those described in the first embodiments and will not repeat here.

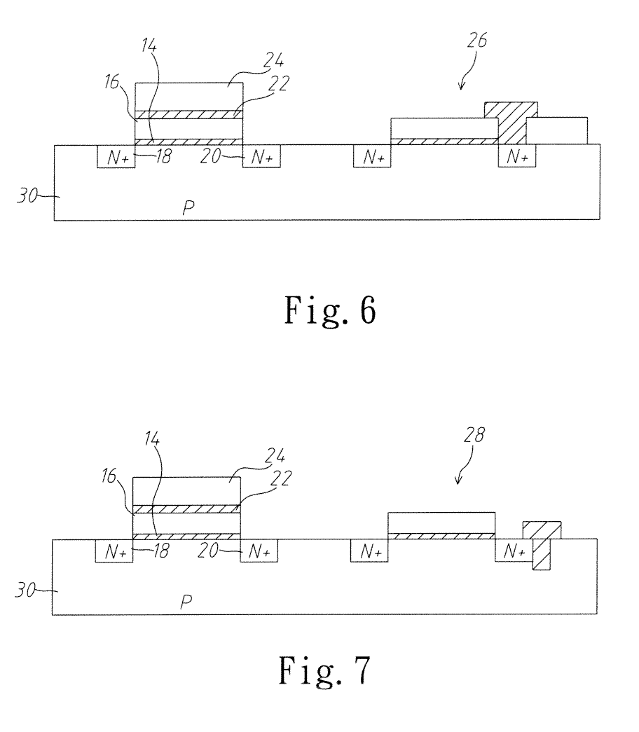

The fabrication of NVM according to the second embodiment of the present invention has been completed in FIG. 5(c). Refer to FIG. 6 for the integration of NVM and DRAM, wherein a stack-type capacitor structure 26 is formed on the p-type semiconductor substrate 30. If the DRAM has a trench-type capacitor structure, form a trench-type capacitor structure 28 in the p-type semiconductor substrate 30 after the step of FIG. 5(a). Then, sequentially undertake the steps of FIG. 4(b) and FIG. 4(c) to form the structure shown in FIG. 7. The objectives and efficacies of integrating NVM and DRAM in the second embodiment are the same as those described in the first embodiment and will not repeat here.

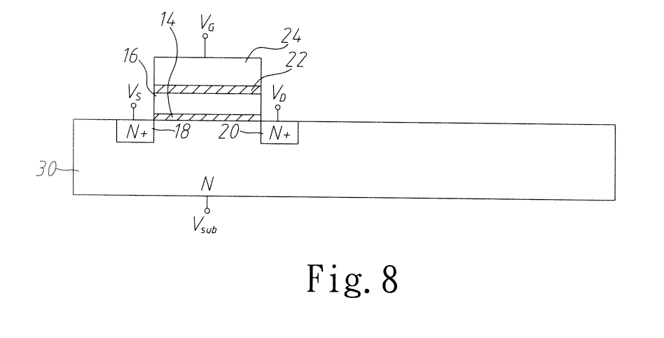

The second embodiment is different from the first embodiment only in that no well is formed in the second embodiment. In the operation of the second embodiment, a substrate voltage V_{sub} applying to the p-type semiconductor substrate 30 replaces the well voltage V_{well} in the first embodiment to achieve the same function. Refer to FIG. 8. In the operation of a nonvolatile memory fabricated according to the second embodiment of the present invention, a drain voltage V_{D}, a source voltage V_{S}, a gate voltage V_{G} and a substrate voltage V_{sub} are respectively applied to the abovementioned drain, source, control gate and p-type semiconductor substrate 30. In a write activity, the abovementioned voltages satisfy the following conditions: V_{sub} is grounded; V_{D}>V_{S}>0, and V_{G}>V_{S}>0. In an erase activity, the abovementioned voltages satisfy the following conditions: V_{sub} is grounded; V_{D}>>V_{S}>0, and V_{G} V_{S}>0.

In the above description of the second embodiment, an n-type transistor is used to exemplify the second embodiment of the present invention. The second embodiment of the present invention also applies to a p-type transistor, wherein the p-type semiconductor substrate 30 and the n-type heavily-doped areas 18 and 20 are respectively replaced by an n-type semiconductor substrate and two p-type heavily-doped areas.

In the operation of a p-type transistor of the second embodiment, a drain voltage V_{D}, a source voltage V_{S}, a gate voltage V_{G} and a substrate voltage V_{sub} are respectively applied to the drain, source, control gate and n-type semiconductor substrate. In a write activity, the abovementioned voltages satisfy the following conditions: V_{sub}>V_{S}>V_{D}, and V_{sub}>V_{S}>V_{G}. In an erase activity, the abovementioned voltages satisfy the following conditions: V_{sub}=V_{S}≧V_{G}>V_{D}.

In conclusion, the present invention not only reduces the costs of fabrication and package but also increases the transmission speed of signals.

The embodiments described above are only to exemplify the present invention but not to limit the scope of the present invention. Any equivalent modification or variation according to the structures, characteristics or spirit disclosed in the specification is to be also included within the scope of the present invention, which is based on the claims stated below.

What is claimed is:

1. A method for integrating a dynamic random access memory and a nonvolatile memory, comprising:
step (A) providing a semiconductor substrate of a dynamic random access memory;
step (B) sequentially forming on a portion of surface of said semiconductor substrate a first gate insulation layer and a first gate layer functioning as a floating gate; and
step (C) implanting ion into regions of said semiconductor substrate, which are at two sides of said first gate insulation layer, to form two heavily-doped areas that are adjacent to said first gate insulation layer and respectively function as a drain and a source; respectively forming over said first gate layer a second gate insulation layer and a second gate layer functioning as a control gate.

2. The method for integrating a dynamic random access memory and a nonvolatile memory according to claim 1, wherein said semiconductor substrate is a p-type semiconductor substrate, and said heavily-doped areas are n-type heavily-doped areas.

3. The method for integrating a dynamic random access memory and a nonvolatile memory according to claim 2, wherein in operation, a drain voltage V_{D}, a source voltage V_{S}, a gate voltage V_{G} and a substrate voltage V_{sub} are respectively applied to said drain, said source, said control gate and said semiconductor substrate, and wherein said voltages satisfy following conditions:
in a write activity, V_{sub} is grounded, and
V_{D}>V_{S}>0, and
V_{G}>V_{S}>0;
in an erase activity, V_{sub} is grounded, and
V_{D}>>V_{S}≧0, and
V_{G}≧V_{S}≧0.

4. The method for integrating a dynamic random access memory and a nonvolatile memory according to claim 1, wherein said semiconductor substrate is an n-type semiconductor substrate, and said heavily-doped areas are p-type heavily-doped areas.

5. The method for integrating a dynamic random access memory and a nonvolatile memory according to claim 4, wherein in operation, a drain voltage V_{D}, a source voltage V_{S}, a gate voltage V_{G} and a substrate voltage V_{sub} are respectively applied to said drain, said source, said control gate and said semiconductor substrate, and wherein said voltages satisfy following conditions:
in a write activity,
V_{sub}>V_{S}>V_{D}, and
V_{sub}>V_{S}>V_{G};
in an erase activity,
V_{sub}=V_{S}≧V_{G}>V_{D}.

6. The method for integrating a dynamic random access memory and a nonvolatile memory according to claim 1, wherein said semiconductor substrate is an n-type semiconductor substrate, and said ion is n-type ion, and said heavily-doped areas are n-type heavily-doped areas, and wherein after said step (A), a p-type well is formed in said semiconductor substrate, and then said step (B) and said step (C) are undertaken to form said heavily-doped areas in said p-type well, and wherein said first gate insulation layer is formed on surface of said p-type well.

7. The method for integrating a dynamic random access memory and a nonvolatile memory according to claim 6, wherein in operation, a drain voltage V_{D}, a source voltage V_{S}, a gate voltage V_{G} and a well voltage V_{well} are respectively applied to said drain, said source, said control gate and said p-type well, and wherein said voltages satisfy following conditions:
in a write activity, V_{well} is grounded, and
V_{D}>V_{S}>0, and
V_{G}>V_{S}>0;
in an erase activity, V_{well} is grounded, and
V_{D}>>V_{S}≧0, and
V_{G}≧V_{S}≧0

8. The method for integrating a dynamic random access memory and a nonvolatile memory according to claim 1, wherein said semiconductor substrate is a p-type semiconductor substrate, and said ion is p-type ion, and said heavily-doped areas are p-type heavily-doped areas, and wherein after said step (A), an n-type well is formed in said semiconductor substrate, and then said step (B) and said step (C) are undertaken to form said heavily-doped areas in said n-type well, and wherein said first gate insulation layer is formed on surface of said n-type well.

9. The method for integrating a dynamic random access memory and a nonvolatile memory according to claim 8, wherein in operation, a drain voltage V_{D}, a source voltage V_{S}, a gate voltage V_{G} and a well voltage V_{well} are respectively applied to said drain, said source, said control gate and said n-type well, and wherein said voltages satisfy following conditions:
in a write activity,
V_{well}>V_{S}>V_{D}, and
V_{well}>V_{S}>V_{G};
in an erase activity,
V_{well}=V_{S}≧V_{G}>V_{D}.

10. The method for integrating a dynamic random access memory and a nonvolatile memory according to claim 1, wherein in said step (C), said two heavily-doped areas are formed in said semiconductor substrate firstly, and then said second gate insulation layer and said second gate layer are sequentially formed over said first gate layer.

11. The method for integrating a dynamic random access memory and a nonvolatile memory according to claim 1, wherein in said step (C), said second gate insulation layer and said second gate layer are sequentially formed over said first gate layer firstly, and then said two heavily-doped areas are formed in said semiconductor substrate.

12. The method for integrating a dynamic random access memory and a nonvolatile memory according to claim 1, wherein after said step (A), a trench-type capacitor structure is formed in said semiconductor substrate, and then said step (B) and said step (C) are sequentially undertaken.

13. The method for integrating a dynamic random access memory and a nonvolatile memory according to claim 1, wherein after said step (C), a stack-type capacitor structure is formed in said semiconductor substrate.

14. The method for integrating a dynamic random access memory and a nonvolatile memory according to claim 1, wherein said first gate layer and said second gate layer are made of a polysilicon material.

15. The method for integrating a dynamic random access memory and a nonvolatile memory according to claim 1, wherein said first gate insulation layer is made of silicon dioxide.

16. The method for integrating a dynamic random access memory and a nonvolatile memory according to claim 1, wherein said second gate insulation layer is an ONO (Oxide-Nitride-Oxide) layer or a TEOS (tetraethyl-ortho-silicate) layer.
